(19) United States
(12) Patent Application Publication
(10) Pub. No.: US 2026/0026023 A1
(43) Pub. Date: Jan. 22, 2026

(54) VERTICAL HETEROJUNCTION BIPOLAR TRANSISTOR

(71) Applicant: GlobalFoundries U.S. Inc., Malta, NY (US)

(72) Inventors: Alexander M. Derrickson, Saratoga Springs, NY (US); Crystal Rose Kenney, Waterford, NY (US); Vibhor Jain, Clifton Park, NY (US); John J. Pekarik, Underhill, VT (US); Judson Robert Holt, Ballston Lake, NY (US); Mona Nafari, Clifton Park, NY (US)

(21) Appl. No.: 18/774,246

(22) Filed: Jul. 16, 2024

(51) Int. Cl. H01L 29/737; H01L 29/06; H01L 29/10; H01L 29/165; H01L 29/66

(52) U.S. Cl. CPC H10D 10/821; H10D 10/021; H10D 62/115; H10D 62/177; H10D 62/822

(57) ABSTRACT

The present disclosure relates to semiconductor structures and, more particularly, to vertical heterojunction bipolar transistors and methods of manufacture. The structure includes: a sub-collector region; a collector region above the sub-collector region; a base region above the collector region; an emitter region over a portion of the base region; and an undercut region bounded vertically and laterally by the base region and adjacent to the emitter region.

This invention was made with government support under Contract #HR0011-203-0002 awarded by DARPA-T-MUSIC. The government has certain rights in the invention.

### BACKGROUND

The present disclosure relates to semiconductor structures and, more particularly, to vertical heterojunction bipolar transistors and methods of manufacture.

A heterojunction bipolar transistor is a type of bipolar junction transistor which uses differing semiconductor materials for the emitter and base regions, creating a heterojunction. The heterojunction bipolar transistor can handle signals of very high frequencies, up to several hundred GHz. The heterojunction bipolar transistor may be used in modern ultrafast circuits including radio frequency (RF) systems, and in applications requiring a high power efficiency, such as RF power amplifiers in cellular telephones.

### SUMMARY

In an aspect of the disclosure, a structure comprises: a sub-collector region; a collector region above the sub-collector region; a base region above the collector region; an emitter region over a portion of the base region; and an undercut region bounded vertically and laterally by the base region and adjacent to the emitter region.

In an aspect of the disclosure, a structure comprises: a heterojunction bipolar transistor comprising a base region, a collector region and an emitter region; and an undercut region bounded on a lateral surface and a vertical surface by the base region.

In an aspect of the disclosure, a method comprises: forming a sub-collector region; forming a collector region above the sub-collector region; forming a base region above the collector region; forming an emitter region over a portion of the base region; and forming an undercut region bounded vertically and laterally by the base region and adjacent to the emitter region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows a structure and respective fabrication processes in accordance with additional aspects of the present disclosure.

FIG. 3 shows a structure and respective fabrication processes in accordance with further aspects of the present disclosure.

FIG. 4 shows a structure and respective fabrication processes in accordance with further aspects of the present disclosure.

FIGS. 5A-5H show fabrication processes of a structure in accordance with aspects of the present disclosure.

### DETAILED DESCRIPTION

The present disclosure relates to semiconductor structures and, more particularly, to vertical heterojunction bipolar transistors and methods of manufacture. More specifically, the present disclosure is directed to a vertical heterojunction bipolar transistor with an undercut (e.g., undercut profile) bounded laterally and vertically by single crystalline semiconductor material. The vertical heterojunction bipolar transistor may also include a collector region comprising two different semiconductor materials. Advantageously, the present disclosure provides the ability to control the processes of fabricating an undercut structure to achieve a high performance device with improved cross wafer variations. In addition, the high performance device does not include any additional SiGe layers under the active collector region which, in turn, improves Rth.

In more specific embodiments, the bipolar transistor comprises an emitter region, a base region and a collector region arranged in a vertical orientation, with the base extending laterally beyond the emitter region and a portion of the collector region. The base region may be, for example, single crystal semiconductor material, e.g., single crystalline SiGe material. A cavity or undercut (hereinafter referred to as an undercut) extends under and on sides of the base region, with the undercut filled with insulator material or devoid of any fill material thereby resulting in an airgap. In embodiments, the undercut may be laterally and vertically bounded by the single crystal SiGe material of the base region. In further embodiments, the collector region may be composed of different semiconductor materials. For example, in embodiments, a lateral width of the collector region comprising Si material may be bounded by single crystal SiGe material.

The vertical heterojunction bipolar transistors of the present disclosure can be manufactured in a number of ways using a number of different tools. In general, though, the methodologies and tools are used to form structures with dimensions in the micrometer and nanometer scale. The methodologies, i.e., technologies, employed to manufacture the vertical heterojunction bipolar transistor of the present disclosure have been adopted from integrated circuit (IC) technology. For example, the structures are built on wafers and are realized in films of material patterned by photolithographic processes on the top of a wafer. In particular, the fabrication of the vertical heterojunction bipolar transistors uses three basic building blocks: (i) deposition or growth of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

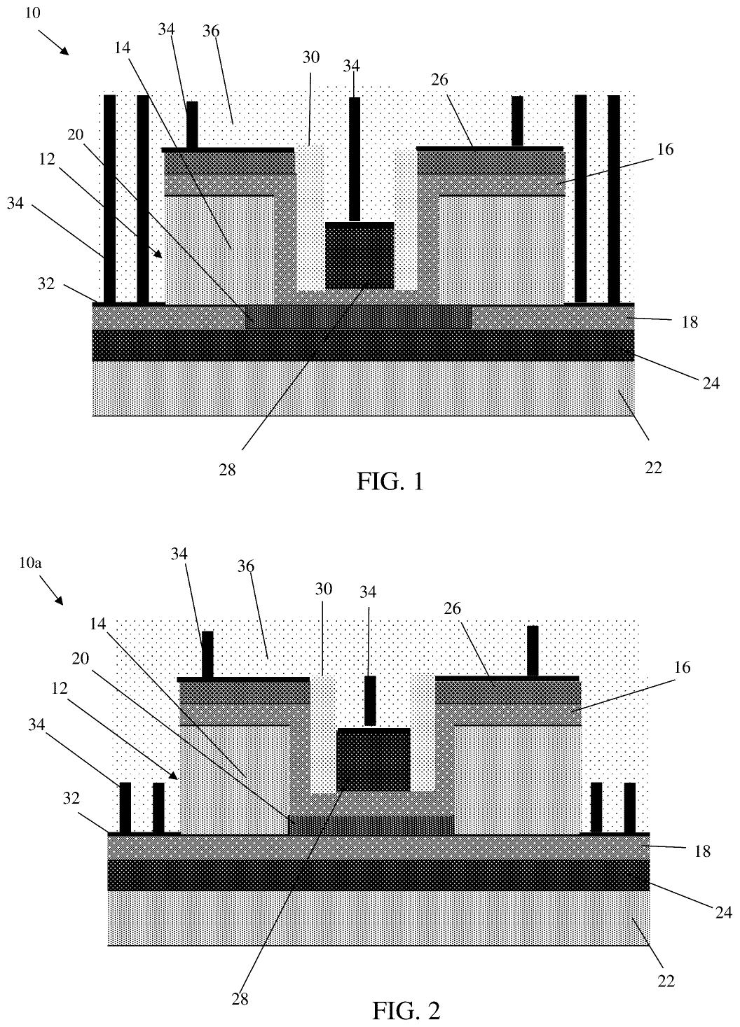

FIG. 1 shows a structure and respective fabrication processes in accordance with aspects of the present disclosure. In particular, the structure 10 of FIG. 1 may be a vertical heterojunction bipolar transistor with an undercut region 12 filled with insulator material 14 and which is bounded laterally and vertically by semiconductor material of a base region 16. The base region 16 may be single crystalline SiGe material. In embodiments, the SiGe material may have a uniform concentration of Ge (e.g., same material composition). In embodiments, the insulator material 14 may be silicon dioxide or other interlevel dielectric or insulator material. The undercut region 12 may be provided above a collector region 18, 20 comprising different semiconductor materials. For example, the collector region 18 may be single crystalline SiGe material; whereas the collector region 20 may be single crystalline Si material. In this way, the collector region 20 is bounded on its lateral edges by the collector region 18.

In more specific embodiments, the structure 10 of FIG. 1 includes a sub-collector region 24 formed in a semiconductor substrate 22. The semiconductor substrate 22 may be single crystalline semiconductor material, e.g., Si, with a suitable crystallographic orientation (e.g., a (100), (110), (111), or (001) crystallographic orientation). As should be understood by those of skill in the art, the semiconductor substrate 22 may be a p-type semiconductor substrate as is known in the art such that no further explanation is required for a complete understanding of the present invention. The semiconductor substrate 22 may either be a bulk semiconductor material or, alternatively, a semiconductor-on-insulator substrate formed by any suitable process, such as separation by implantation of oxygen (SIMOX), oxidation, deposition, and/or other suitable process.

The sub-collector region 24 may be formed in the semiconductor substrate 22 by an ion implantation process with an N+ type dopant. In embodiments, the N+ type dopant may be, for example, Arsenic (As), Phosphorus (P) and Antimony (Sb), among other suitable examples. The ion implantation process may use a patterned implantation mask to define selected areas exposed for the implantation. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions. An annealing process may be used to drive the dopant into the semiconductor substate 22.

FIG. 1 further shows the collector regions 18, 20 formed over the sub-collector region 24. In embodiments, the collector region 18 may be SiGe material and the collector region 20 may be, for example, Si material. The SiGe material and Si material may be single crystalline semiconductor material. The collector region 18 may be formed by an epitaxial growth process with an in-situ doping process. In embodiments, the in-situ doping process includes an N+ type dopant, e.g., Arsenic. The collector region 20 may be formed by etching a trench into the collector region 18, followed by an epitaxial growth process. In embodiments, the collector region 20 may be single crystalline Si material which is bounded on its lateral edges by the collector region 18 comprising the SiGe material. The collector region 20 may be at a same height, e.g., planar, with the collector region 18 or, alternatively, the collector region 20 may be above or below a top surface, e.g., recessed, with respect to the collector region 18.

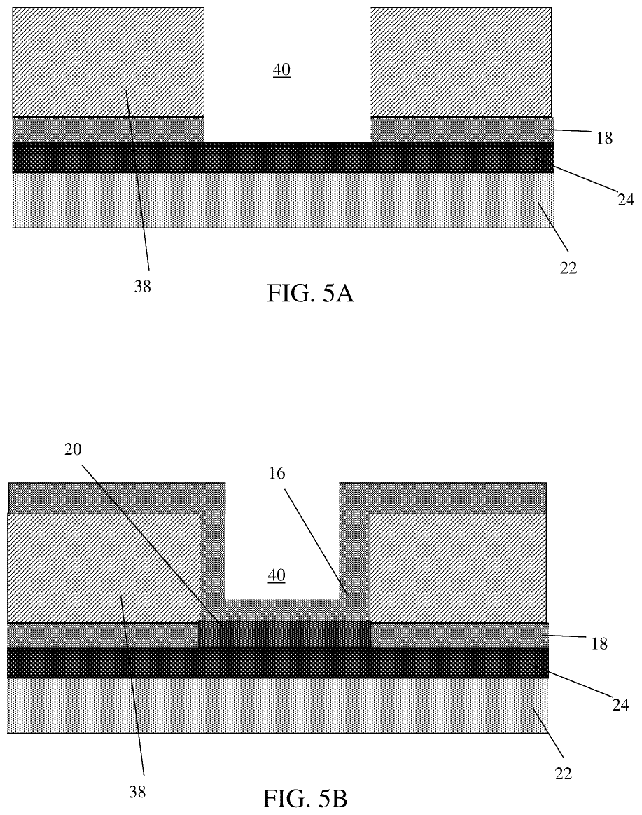

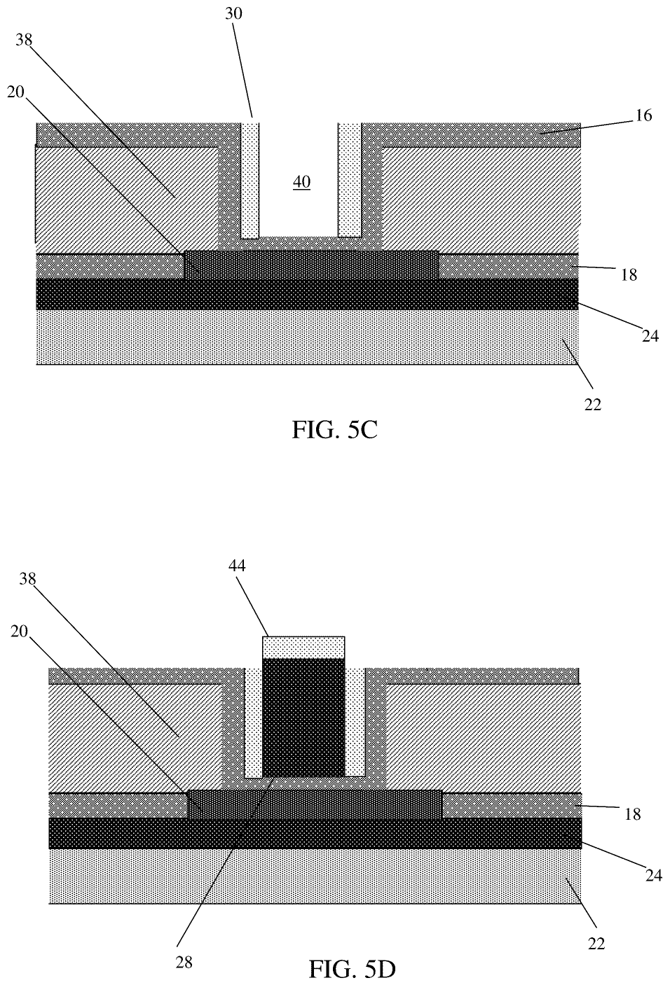

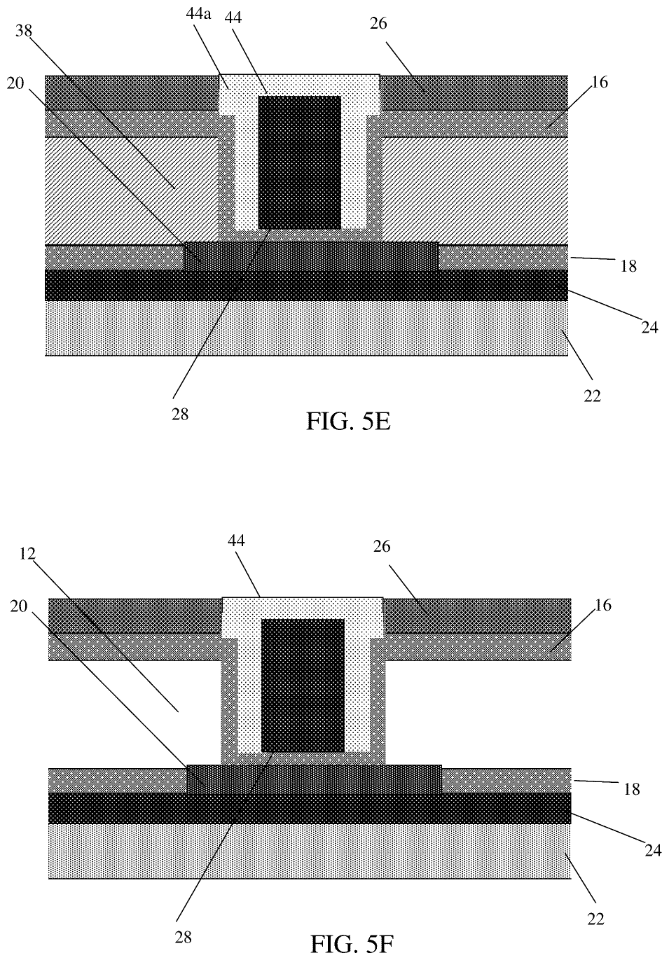

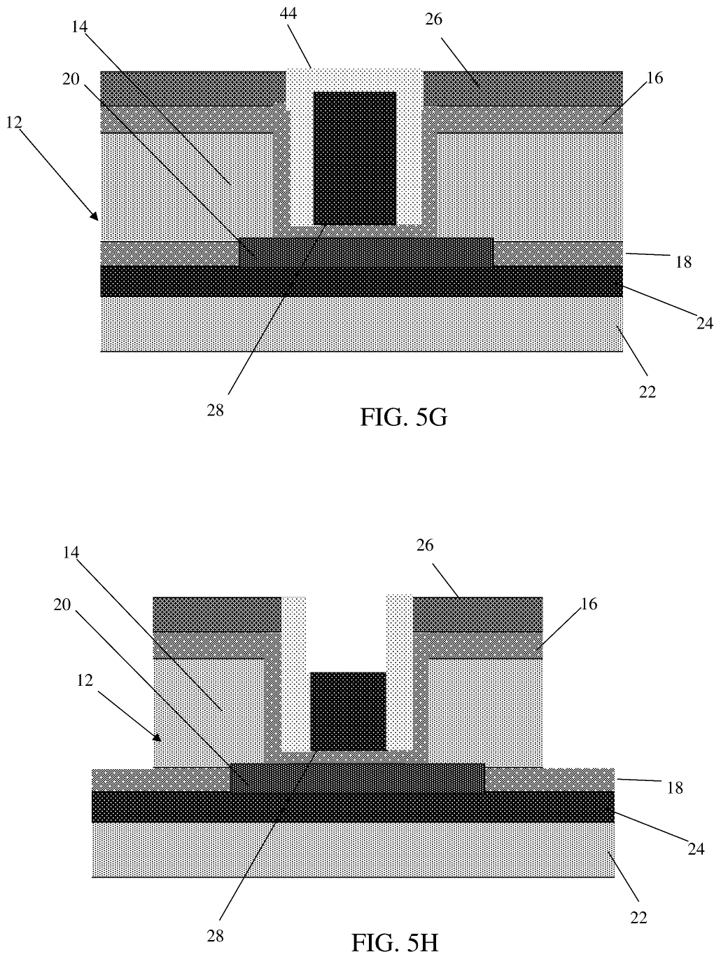

As described in more detail with respect to FIG. 5F, an undercut 12 may be formed above the collector regions 18, 20 and below and to the side of the base region 16. The undercut 12 may be filled with insulator material 14 and, hence is laterally and vertically bound by the semiconductor material of the base region 16. For example, the semiconductor material, e.g., SiGe material, of the base region 16 may be on the vertical sidewalls and horizonal, top surface of the insulator material 12. In embodiments, the insulator material 14 may be silicon dioxide or other insulator materials such as silicon nitride, etc.

The base region 16 may be an intrinsic base above and in direct physical contact with the collector region 20. The base region 16 may be SiGe material and more specifically, p-type single crystalline SiGe material. The base region 16 may be formed by epitaxial growth process with an in-situ doping process as described in more detail with respect to FIG. 5B. In embodiments, the Ge concentration may be constant throughout the base region 16. In further embodiments, the in-situ doping process includes a P+ type dopant, e.g., Boron. An extrinsic base 26 may be formed over the base region 16 and the insulator material 14. As described herein, the extrinsic base 26 may be formed by an epitaxial growth process with an in-situ doping, e.g., p-type dopant. The extrinsic base 26 may be single crystalline SiGe with a constant concentration of Ge.

FIG. 1 further shows an emitter region 28 formed over and in direct contact with a top surface, e.g., lateral surface, of the base region 16. In embodiments, the emitter region 28 may be a self-aligned emitter region as described with respect to FIG. 5D. The emitter region 28 may be, for example, n-doped Si material. The emitter region 28 may be formed by epitaxial growth process with an in-situ doping process as described herein. In embodiments, the bottom of the emitter region 28 is below the top of the undercut 12 and, in further embodiments, the bottom of the emitter region 28 is above a bottom of the insulator material 14 in the undercut 12. Sidewall spacers 30 may be formed between the vertical sidewalls of the base region 16 and the emitter region 28. The sidewall spacers 30 may be any insulator material, e.g., nitride or oxide based materials.

A silicide contact 32 may be formed on the extrinsic base region 26, the emitter region 28 and the collector region 18. As should be understood by those of skill in the art, the silicide process begins with deposition of a thin transition metal layer, e.g., nickel, cobalt or titanium, over fully formed and patterned semiconductor devices (e.g., extrinsic base region 26, emitter region 28 and collector region 18). After deposition of the material, the structure is heated allowing the transition metal to react with exposed silicon (or other semiconductor material as described herein) in the active regions of the semiconductor device (e.g., extrinsic base region 26, emitter region 28 and collector region 18) forming a low-resistance transition metal silicide. Following the reaction, any remaining transition metal is removed by chemical etching, leaving silicide contacts in the active regions of the device.

Contacts 34 may be formed on the silicide contacts 32. In embodiments, the contacts 34 may be any back end of the line metal. For example, the contacts 34 may be Tungsten, Copper, Aluminum, TiN, etc. In embodiments, the contacts 34 may be formed in interlevel dielectric material 36 using conventional lithography, etching and deposition methods known to those of skill in the art.

By way of example of forming the contacts 34, a resist formed over the interlevel dielectric material 36 is exposed to energy (light) and developed utilizing a conventional resist developer to form a pattern (e.g., openings). An etching process with a selective chemistry, e.g., reactive ion etching (RIE), will be used to transfer the pattern from the patterned photoresist to the interlevel dielectric material 36, forming trenches in the interlevel dielectric material 36 that expose the silicide contacts 32. Following the resist removal by a conventional oxygen ashing process or other known stripant, conductive material may be deposited in the trenches by any conventional deposition processes, e.g., chemical vapor deposition (CVD) processes. Any residual material on the surface of the interlevel dielectric material 36 can be removed by conventional chemical mechanical polishing (CMP) processes.

FIG. 2 shows a structure in accordance with additional aspects of the present disclosure. In the structure 10a of FIG. 2, the collector region 20 may be formed above the collector region 18. In this configuration, the collector region 20 may be on sides of the insulator material 14 that is within the undercut 12. Accordingly, the insulator material 14 of the undercut 12 may be bounded on its vertical sidewalls by the base region 16 and the lateral edges of the collector region 20 at a lower portion thereof. The collector region 20 may be Si material and the underlying collector region 18 may be SiGe material. The base region 16, e.g., intrinsic base region, may be formed above and in direct contact with the collector region 20. The remaining features of the structure 10a are similar to the structure 10 of FIG. 1 such that no further explanation is required for a complete understanding of the present disclosure.

FIG. 3 shows another structure in accordance with additional aspects of the present disclosure. In the structure 10b of FIG. 3, the extrinsic base region 26 may be formed between the insulator material 14 and the intrinsic base region 16. In this configuration, the insulator material 14 is still bounded both laterally and vertically by the base region 16 and, more specifically, in direct contact on a top surface by the semiconductor material of the base region 26 and in direct contact on the vertical sidewall by the semiconductor material of the base region 16. In this configuration, the intrinsic base region 16 may act as the extrinsic base region with the silicide contacts 32 and contact 34 formed on the lateral portion (e.g., horizontal surface) of the base region 16.

Similar to the structure 10 shown in FIG. 1, the collector region 20 may be formed within the trench of the collector region 18 or, alternatively, as shown in the structure 10a of FIG. 2, the collector region 20 may be formed above the collector region 18. Accordingly, it is contemplated herein that the collector region 20 may be above, below or planar with a top surface of the collector region 18. The remaining features of the structure 10a are similar to the structure 10 of FIG. 1 such that no further explanation is required for a complete understanding of the present disclosure.

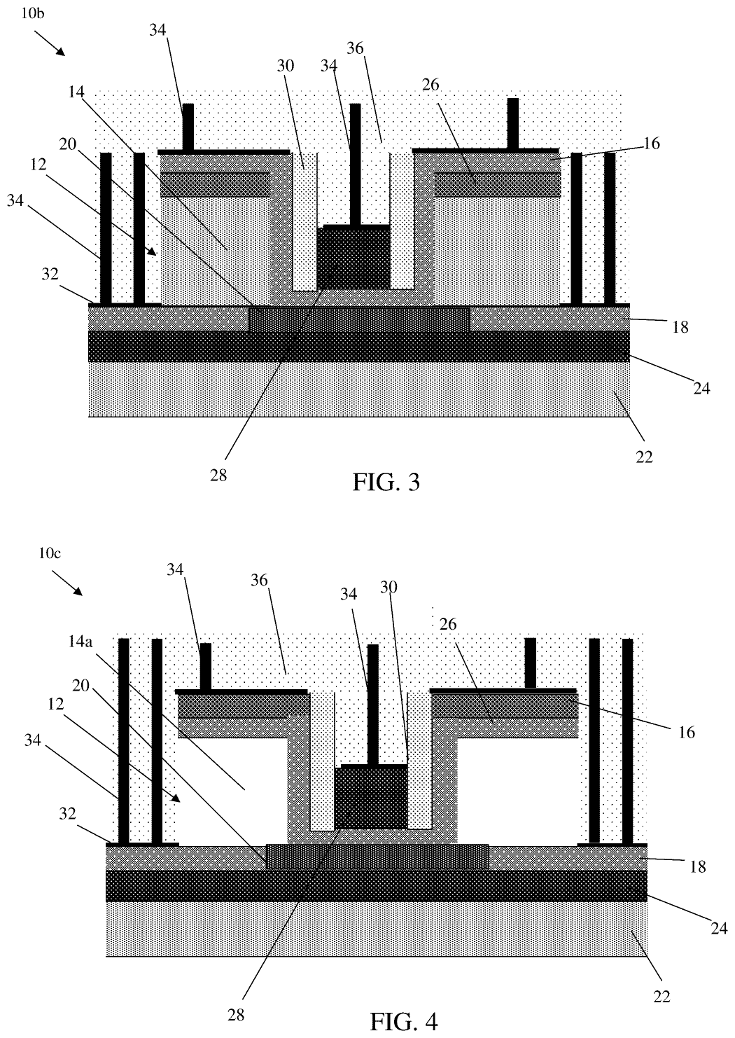

FIG. 4 shows another structure 10c in accordance with aspects of the present disclosure. In the structure 10c of FIG. 3, the undercut region 12 is not filled with any insulator material, resulting in an airgap 14a. Alternatively, the undercut region 12 can be partially filled with insulator material which will result in a smaller airgap 14a. The airgap 14a may be formed by a pinch-off process during the deposition of the interlevel dielectric material 36 as is known to those of skill in the art such that no further explanation is required for a complete understanding of the present disclosure.

In embodiments, the airgap 14a is bounded laterally and vertically by the interlevel dielectric material 36 and the semiconductor material of the base region 16. It should also be recognized that the airgap 14a may be bounded laterally and vertically by the base regions 16, 26 as shown in FIG. 3. In addition, it should be recognized that the collector region 20 may be within a trench of the collector region 18 or, as shown in FIG. 2, above the collector region 20. The remaining features of the structure 10c are similar to the structure 10 of FIG. 1 such that no further explanation is required for a complete understanding of the present disclosure.

FIGS. 5A-5H show fabrication processes in accordance with aspects of the present disclosure. The fabrication processes shown in these figures represent the fabrication of the structure 10 of FIG. 1. It should be recognized by those of skill in the art, though, that similar fabrication processes can be used for the structures shown in FIGS. 2-4. For example, the structure 10a shown in FIG. 2 may omit the formation of a trench in the collector region 18 and, instead, after forming the trench of FIG. 5A, deposit different semiconductor material on top of the collector region 18 to form collector region 20.

In FIG. 5A, for example, the semiconductor substrate 22 undergoes an ion implantation process to form the sub-collector region 24 in the semiconductor substate 22. As already described herein, the ion implantation process provides an n-type dopant into the semiconductor substrate 22. The semiconductor substrate 22 is preferably a single crystalline semiconductor material, e.g., Si, with a suitable crystallographic orientation (e.g., a (100), (110), (111), or (001) crystallographic orientation).

As further shown in FIG. 5A, the collector region 18 may be formed on the semiconductor substrate 22. In embodiments, the collector region 18 may be formed by an epitaxially growth process with an in-situ doping process. In embodiments, the collector region 18 may be an epitaxial growth of single crystalline SiGe material with an n-type dopant, e.g., Arsenic.

Examples of various epitaxial growth process apparatuses that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type, as defined below) is typically added to the precursor gas or gas mixture for the in-situ processes.

A semiconductor material 38 may be formed over the collector region 18. In embodiments, the semiconductor material 38 should be a semiconductor material that is selective etchable with respect to the semiconductor material of the collector region 18 and the base region 16 (which is yet to be formed). In preferred embodiments, the semiconductor material 38 may be Si material. A trench 40 is formed through the semiconductor material 38 and the collector region 18 using conventional lithography and etching processes, e.g., RIE, as already described herein.

In FIG. 5B, collector region 20 is formed in the bottom of the trench, followed by formation of the base region 16, e.g., intrinsic base region, within the trench 40 and over the semiconductor material 38. In embodiments, the collector region 20 may be formed by an epitaxial growth process. In this process, the semiconductor material of the collector region 20 may be formed on the semiconductor material 38. In preferred embodiments, the semiconductor material of the collector region and the semiconductor material 38 are the same material, which can be selective to the semiconductor material of the base region 16.

Still referring to FIG. 5B, the base region 16 may be formed by an epitaxial growth process with an in-situ doping process. In embodiments, the semiconductor material of the base region 16 should be selectively etchable with respect to the semiconductor material 38 and the semiconductor material of the collector region 20. For example, the base region 16 may be SiGe material with a p-type dopant. In more preferred embodiments, the base region 16 may be a single crystalline SiGe material.

As further shown in FIG. 5C, sidewall spacers 30 may be formed on the sidewalls of the base region 16 within the trench 40. The sidewalls spacers 30 may be formed by a blanket deposition of insulator material, e.g., nitride or oxide material or combinations thereof, followed by an anisotropic etching process. As should be understood by those of ordinary skill in the art, the anisotropic etching process will remove the insulator material from horizontal surfaces of the structure leaving the sidewall spacers 30 on the vertical sidewalls of the base region 16.

In FIG. 5D, the emitter region 28 is formed within the trench 40 and between the sidewall spacers 30. In embodiments, the emitter region 28 may be semiconductor material and, more specifically, p-type Si material. In embodiments, the emitter region 28 may be formed by an epitaxial growth process with an in-situ p-type (e.g., Boron) doping process.

As further shown in FIG. 5D, a capping material 44 may be formed over the emitter region 28. In embodiments, the capping material 44 may be a hardmask material including, for example, an insulator material. In more specific embodiments, the capping material 44 may be the same material as the sidewall spacers 30. The capping material 44 may be formed by a blanket deposition process, e.g., CVD, followed by a patterning process, e.g., lithography and etching process.

In FIG. 5E, additional spacer material 44a may be deposited on the exposed sides of the emitter region 28, above the base region 16. The additional spacer material 44a may be formed by a blanket deposition process, e.g., CVD, followed by a patterning process, e.g., lithography and etching process. The additional spacer material 44a may be the same material as the sidewall spacers 30, e.g., nitride or oxide or combinations thereof.

The extrinsic base region 26 may be formed over the base region 16. The extrinsic base region 26 may be formed by an epitaxial growth process with an in-situ doping process. The extrinsic base region 26 is preferably a semiconductor material that is selectively etchable with respect to the semiconductor material 38. For example, the extrinsic base region 26 may be p-type single crystalline SiGe material.

In FIG. 5F, an undercut 12 is formed under and on the side of the base region 16. The undercut 12 may be formed by removing the semiconductor material 38 with a selective chemistry. In this way, the selective chemistry will selectively etch the semiconductor material 38, with the base region 16 acting as a control. For example, as the base region 16 comprises different semiconductor material than the semiconductor material 38, it is possible to control the etching process with a selective etching chemistry to remove the semiconductor material 36 with the base region defining the undercut 12. Accordingly, the undercut 12 may be controlled by the semiconductor material, e.g., SiGe material, of the base region 16.

In FIG. 5G, the undercut 12 may be filled with insulator material 14. In alternative embodiments, the undercut 12 may be partially filled with insulator material 14 or remain devoid of any material thereby resulting in an airgap or partial airgap as shown in FIG. 4. The airgap, for example, may be formed by a pinch-off process using a CVD process as is known in the art. In embodiments, the insulator material 14 may be an interlevel dielectric material or other insulator material deposited by a CVD process. As shown in FG. 5G, the undercut 12 and, more particularly, the insulator material 14 in the undercut is bounded laterally and vertically by the semiconductor material of the base region 16.

In FIG. 5H, the cap material may be removed from over the emitter region 28, and the semiconductor material of the emitter region 28 may be recessed using conventional patterning processes as is known in the art. In embodiments, the semiconductor material of the emitter region 28 may be recessed to below a top surface of the extrinsic base region 26 or the base region 16. The semiconductor material of the base regions 16, 26 and the insulator material 14 may be patterned to expose the underlying collector region 18. The processes continue with the formation of the silicide contacts and contacts as described with respect to FIG. 1.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a sub-collector region;
a collector region above the sub-collector region;
a base region above the collector region;
an emitter region over a portion of the base region; and
an undercut region bounded vertically and laterally by the base region and adjacent to the emitter region.

2. The structure of claim 1, wherein the undercut region comprises insulator material bounded vertically and laterally by the base region.

3. The structure of claim 1, wherein the undercut region comprises an airgap bounded vertically and laterally by the base region.

4. The structure of claim 1, wherein the base region comprises single crystalline semiconductor material.

5. The structure of claim 4, wherein the base region comprises an extrinsic base region and an intrinsic base region, the intrinsic base region being between the undercut region and the extrinsic base region.

6. The structure of claim 1, wherein the collector region comprises different semiconductor materials.

7. The structure of claim 6, wherein the different semiconductor materials comprise Si material within a trench of SiGe material such that lateral edges of the Si material are bounded by the SiGe material.

8. The structure of claim 6, wherein the different semiconductor materials comprise Si material above the SiGe material and the Si material partly bounds a vertical sidewall of the undercut region.

9. The structure of claim 1, wherein a bottom of the emitter region is below a top of the undercut region and is separated from lateral walls of the base region by sidewall spacers.

10. A structure comprising:
a heterojunction bipolar transistor comprising a base region, a collector region and an emitter region; and
an undercut region bounded on a lateral surface and a vertical surface by the base region.

11. The structure of claim 10, wherein the base region comprises p-type single crystalline SiGe material.

12. The structure of claim 10, wherein the undercut region is further bounded by the collector region at a lower surface.

13. The structure of claim 10, wherein the undercut region comprises insulator material.

14. The structure of claim 10, wherein the undercut region comprises an airgap.

15. The structure of claim 10, wherein the collector region comprises Si material under the emitter region.

16. The structure of claim 10, wherein the collector region comprises Si material and SiGe material, the Si material being within a trench of the SiGe material.

17. The structure of claim 10, wherein the collector region comprises Si material above SiGe material.

18. The structure of claim 17, wherein the Si material is adjacent to the undercut region on a vertical sidewall thereof.

19. The structure of claim 10, wherein the emitter region has a top surface that is below a portion of the base region.

20. A method comprising:
forming a sub-collector region;
forming a collector region above the sub-collector region;
forming a base region above the collector region;
forming an emitter region over a portion of the base region; and
forming an undercut region bounded vertically and laterally by the base region and adjacent to the emitter region.
